(19) United States
(12) Patent Application Publication
(10) Pub. No.: US 2005/0170668 A1
(43) Pub. Date: Aug. 4, 2005

(54) Plasma chemical vapor deposition system and method for coating both sides of substrate

(75) Inventors: Young-soo Park, Gyeonggi-do (KR); Yuri Tolmachev, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: SAMSUNG ELECTRONICS CO., LTD., Gyeonggi-do (KR)

(21) Appl. No.: 11/044,278

(22) Filed: Jan. 28, 2005

(30) Foreign Application Priority Data
Jan. 30, 2004 (KR) 10-2004-0006105

(51) Int. Cl. H01L 21/31

(52) U.S. Cl. 438/789

(57) ABSTRACT

A plasma chemical vapor deposition system includes a chamber provided with gas injection holes, a gas exhaust unit mounted on the chamber, a substrate holder disposed on a central area of the chamber to support a substrate in a state where both sides of the substrate are exposed, and first and second coils generating induced magnetic fields. The first and second coils are disposed around upper and lower outer circumferences of the chamber, respectively.

### BACKGROUND OF THE INVENTION

Priority is claimed to Korean Patent Application No. 10-2004-0006105, filed on Jan. 30, 2004, in the Korean Intellectual Property Office, the disclosure of which is incorporated herein in its entirety by reference.

1. Field of the Invention

The present invention relates to plasma chemical vapor deposition (CVD) system and method for coating both sides of a substrate, and more particularly, to plasma CVD system and method that can uniformly coat both sides of a substrate with material.

2. Description of the Related Art

Generally, a plastic substrate is lighter than a glass substrate, and is not being easily broken. Therefore, in recent years, plastic substrates have been actively developed as a substitution of the glass substrate used for a thin film transistor (TFT) liquid crystal display (LCD) as well as a material for an organic electroluminiscent (EL) substrate. Since the plastic substrate has less rigidity compared with the silicon or glass substrate, it is easily flexed by outer stress.

Particularly, for the TFT LCD or organic EL display, a variety of layers such as an amorphous silicon layer, a metal layer, a silicon oxide layer, and a silicon nitride layer apply high stress to the substrate. The high stress may not be a fatal problem for the silicon and glass substrates as the substrates have sufficient rigidity against the high stress. However, the high stress may be fatal for the plastic substrate, deteriorating the alignment and cracking the deposited layers.

In a TFT LCD manufacturing process, the highest stress is applied to the substrate in the course of depositing 3000-6000 Å thick silicon oxide layers used as an interlayer dielectric (ILD) layer and an intermetallic dielectric (IMD) layer. Therefore, when the silicon oxide layer is coated on a first side of the substrate, the substrate is to be severely flexed. As a result, even when the substrate is turned over and the silicon oxide layer is coated on a second side of the substrate, it is often cracked at the flexed portion.

FIGS. 1A through 1C show a case where the silicon oxide layer is coated on both sides of a plastic substrate according to the prior art.

FIG. 1A shows a plastic substrate that is severely flexed by coating a 3000 Å thick silicon oxide layer 102 on a first side using an inductive coupling type plasma CVD.

FIG. 1B shows the plastic substrate 101 having both sides that are coated with the silicon oxide layer in turn. Although the plastic substrate 101 is flat, may cracks 103 are incurred at a periphery portion of the plastic substrate 101, which is flexed with a relatively high curvature.

FIG. 1C shows a fractography of the cracked portion. That is, the plastic substrate 101 is severely flexed by depositing the 3000 Å thick silicon oxide layer 102 on the first side of the plastic substrate 101. To flatten the flexed plastic substrate 101, it is turned over and the 3000 Å thick silicon oxide layer 102 on the second side of the plastic substrate 101. In this case, although the plastic substrate 101 is flattened, cracks 103 are generated at the periphery portion of the plastic substrate 101. Therefore, to prevent the cracks from being generated, the silicon oxide layer should be simultaneously deposited on both sides of the plastic substrate.

Accordingly, a both-side coating method has been developed to prevent the above-described problem. The both-side coating method is also required in manufacturing a hard disk and a solar cell. Therefore, a variety of CVD equipments for performing the both-side coating method has been proposed. Japanese patent publication No. H14-093722 discloses a CVD system for coating both sides of a silicon substrate for a solar cell without turning over the silicon substrate. In addition, Japanese patent publication No. H14-105651 discloses a both-side coating apparatus provided with a filament coil for coating both sides of a hard disk with diamond like carbon (DLC). The apparatuses disclosed in these patents are a type of a capacitive plasma CVD system using a cathode and an anode.

However, such a capacitive plasma CVD system has a problem in that a back plate functioning as the anode should be disposed on a rear surface of a high resistance substrate or a dielectric substrate to form a thin film on the substrate. If the back plate is not used, since it is difficult for high frequency current to flow along the substrate, a density of the plasma on a surface of the substrate is remarkably reduced. Accordingly, there may be a thickness difference between a thin film at a central portion and a thin film at a periphery portion, causing a non-uniformity of the film property. The larger the size of the substrate, the more severe the above-described problem. Therefore, it is difficult to practically apply the capacitive plasma CVD system in coating the substrate.

To solve the problems of the capacitive plasma CVD system, PCT publication No. WO2002/581,121 discloses an inductive coupling type plasma generating apparatus.

FIGS. 1d and 1e show such an inductive coupling type plasma CVD system.

As shown in the drawings, two inductively coupled electrodes 11 and 11′ are disposed in a chamber 12. A substrate 13 is mounted on a substrate holder 14 between the electrodes 11 and 11′. The chamber 12 is provided with reacting gas injection holes 15 and 15′ and a gas exhaust hole 16 formed at an opposite side of the reacting gas injection holes 15 and 15′.

The plasma generated at the gas injection holes 15 and 15′ is diffused to reach the substrate 13. Therefore, even when the substrate is a high resistance substrate or a dielectric substrate, the intensity of the high frequency current is not varied regardless of the location of the substrate. However, since the inductive coupling type electrodes 11 and 11′ are formed in the chamber 12, impurities may be mixed with material to be deposited on the substrate 13 by a plasma sputtering or arching phenomenon generated between the electrodes 11 and 11′in the chamber 12.

Furthermore, since the inductive coupling type electrodes 11 and 11′ are fixed on the chamber 12, it is impossible to adjust the location of the electrodes 11 and 11′. As a result, it is difficult to vary the plasma density. In the case of a one-side coating apparatus, since it is impossible to vertically move the substrate, the coating can be realized at the most uniform plasma density between the substrate and the electrodes. However, as shown in FIGS. 1d and 1e, since the electrodes 11 and 11′ between which the substrate 13 is disposed is symmetrically disposed, when the substrate 13 is displaced to uniformly deposit a layer on a side of the substrate, the uniformity of the other side is deteriorated.

### SUMMARY OF THE INVENTION

The present invention provides a plasma CVD system for coating both sides of a substrate, which is designed to uniformly distribute a plasma density to provide a uniform coating layer on the both sides of the substrate.

According to an aspect of the present invention, there is provided a plasma chemical vapor deposition system comprising a chamber provided with gas injection holes; a gas exhaust unit mounted on the chamber; a substrate holder disposed on a central area of the chamber to support a substrate in a state where both sides of the substrate are exposed; and first and second coils generating induced magnetic fields, the first and second coils being disposed around upper and lower outer circumferences of the chamber, respectively.

The substrate holder may be disposed enclosing an outer circumference of the substrate holder.

The gas exhaust unit may be provided at an inner circumference with an inner gas exhaust hole through which the gas in the chamber is exhausted and at an outer circumference with an outer exhaust hole connected to a pump.

The inner gas exhaust hole may be formed at least two portions of the inner circumference of the gas exhaust unit, each size of the inner exhaust holes being increased as it goes away from the outer exhaust hole.

The first and second coils may be formed of one of helical type coils or flat antenna type coils and disposed to be movable along the outer circumference of the chamber so that a distance between the first and second coils can be adjustable.

The first and second coils may be symmetrically disposed with reference to the substrate holder.

First ends of the first and second coils shares a high frequency generator and second ends of the first and second coils are respectively connected to first and second tuning capacitors.

The gas injection holes may be symmetrically formed on opposing ends of the chamber.

According to another aspect of the present invention, there is provided a plasma chemical vapor deposition method comprising disposing a substrate on a substrate holder in a central area of a chamber provided with a gas injection hole and a gas exhaust hole; and generating uniform induced magnetic fields on both sides of the substrate by applying high frequency to first and second coils between which the substrate is disposed, thereby forming a uniform thin film on the both sides of the substrate.

### BRIEF DESCRIPTION OF THE DRAWINGS

The above and other features and advantages of the present invention will become more apparent by describing in detail exemplary embodiments thereof with reference to the attached drawings in which:

FIG. 1A is a view of a plastic substrate that is severely flexed by coating a silicon oxide layer on a first side of the plastic substrate according to the prior art;

FIG. 1B is a view illustrating a case where the plastic substrate depicted in FIG. 1A is turned over and a silicon oxide layer is coated on a second side of the plastic substrate according to the prior art;

FIG. 1C is a fractography of a cracked portion of a silicon oxide layer coated on a plastic substrate using a conventional plasma CVD system.

FIGS. 1D and 1E are views of a conventional inductive coupling type plasma CVD system;

FIG. 2A is a sectional view of a plasma CVD system according to an embodiment of the present invention;

FIG. 2B is a view of a gas exhaust unit used for a plasma CVD system according to an embodiment of the present invention;

FIG. 3A is a graph illustrating a magnetic field distribution when a coil is disposed on one side of a chamber of a plasma CVD system;

FIGS. 3B and 3C are graphs illustrating a magnetic field distribution when two coils are disposed on both sides of a chamber of a plasma CVD system according to an embodiment of the present invention;

FIGS. 4A through 4C are graphs illustrating a magnetic field distribution according to a coil structure and a distance between coils of a plasma CVD system of the present invention; and

FIG. 4D is a graph illustrating a plasma density distribution on a substrate according to a plasma density distribution on an inner circumference of a chamber of a plasma CVD system of the present invention.

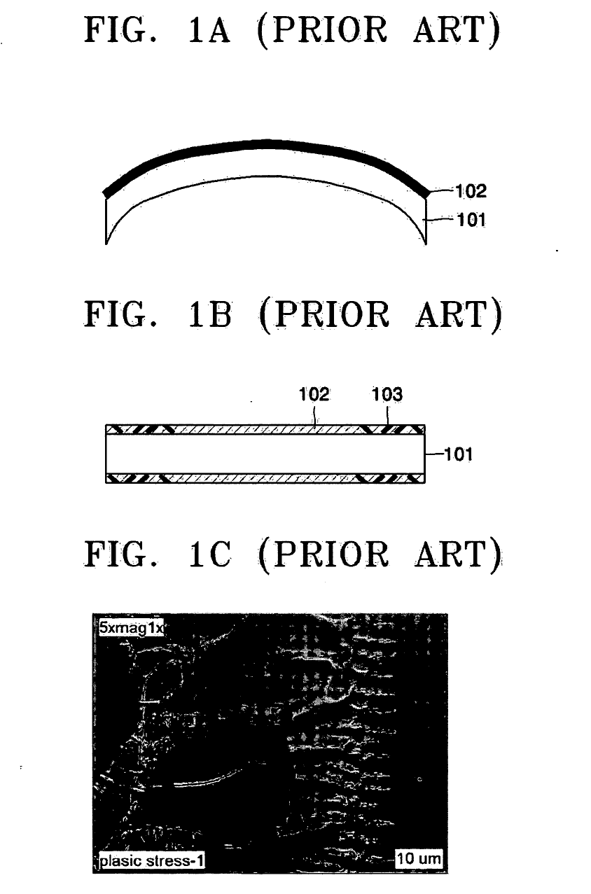

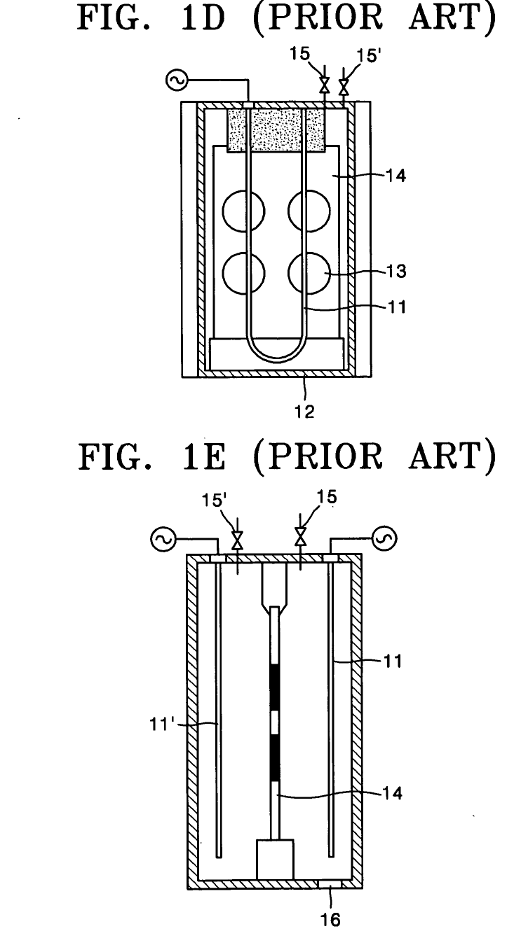

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

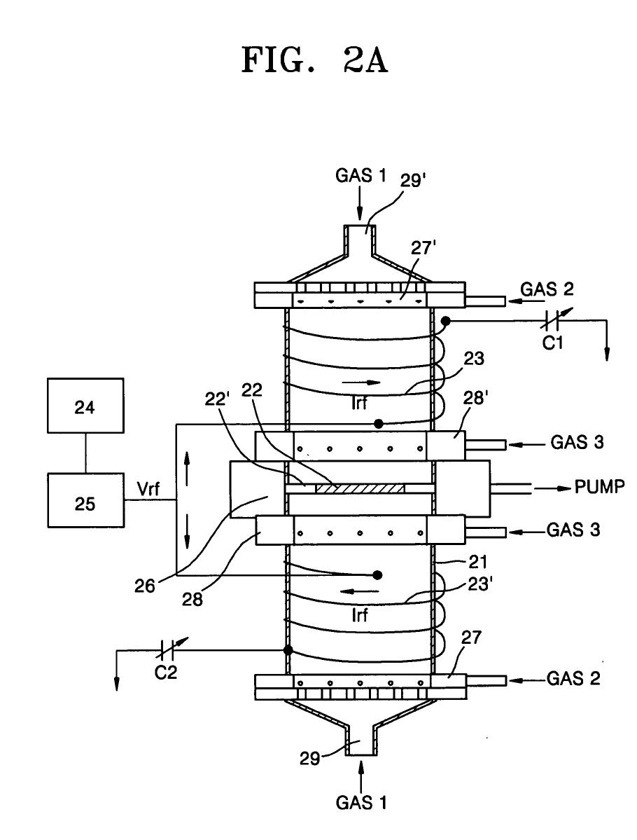

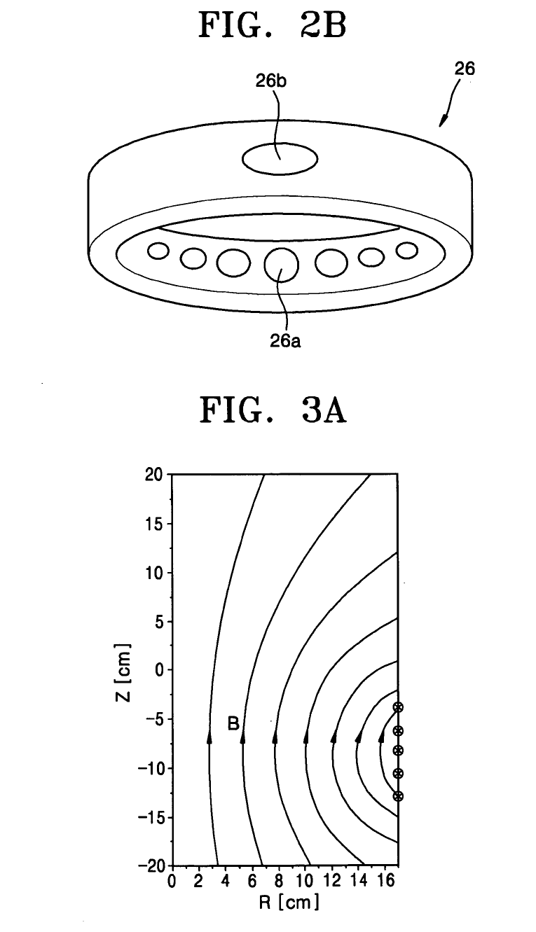

Referring first to FIG. 2A, a substrate 22 to be deposited with a desired material is mounted on a substrate holder 22′ in a chamber 21. First and second coils 23 and 23′generating an induced magnetic field are disposed around upper and lower circumferences of the chamber 21 with reference to the substrate 22. The first and second coils 23 and 23′ may be helical type coils or flat antenna type coils facing each other. First ends of the coils 23 and 23′ are electrically connected to a matching box 25 connected to a high frequency generator 24 and second ends of the coils 23 and 23′ are respectively connected to tuning capacitors C1 and C2. As described above, a feature of the present invention is that the coils 23 and 23′generating the induced magnetic field are disposed around the upper and lower circumferences of the chamber 21.

The chamber 21 is provided with a plurality of gas injection holes through which gas for generating plasma and reacting gas to be deposited on the substrate 22 can be injected into the chamber 21. In order to coat both sides of the substrate 22, the injection holes may be symmetrically formed on both sides of the chamber 21. However, the present invention is not limited to this structure.

A gas exhaust unit 26 is disposed around a central circumference of the chamber 21. A size of an exhaust hole of the gas exhaust unit 26 may be properly adjusted to uniformly exhaust the reacting gas out of the chamber 21.

FIG. 2B shows an embodiment of the gas exhaust unit 26.

The gas exhaust unit 26 is provided at an inner circumference with inner gas exhaust holes 26a through which the gas in the chamber 21 is exhausted and at an outer circumference with an outer exhaust hole 26b connected to a pump (see FIG. 2A). Each size of the inner exhaust holes 26a is increased as it goes away from the outer exhaust hole 26b to uniformly exhaust the gas out of the chamber 21.

In the above-described plasma CVD system, uniform plasma can be generated in the chamber 21 by the coils 23 and 23′ disposed around the upper and lower circumference of the chamber 21. The uniformly generated plasma is diffused to the substrate 22 disposed on a central portion in the chamber 21 between the coils 23 and 23′, thereby uniformly forming desired layers on both sides of the substrate 22. The chamber 21 may be formed of a quartz tube. The coils 23 and 23′ are designed to freely displace along the outer circumference of the chamber 21, thereby making it possible to adjust a plasma density distribution between the substrate 22 and the plasma generating portions in the chamber 21. Even when the coils 23 and 23′ are designed not to freely displace, since the coils 23 and 23′ are respectively connected to the capacitors C1 and C2, an amount of current applied to the coils 23 and 23′ can be adjusted. Accordingly, the plasma density distribution can be adjusted by adjusting the amount of the current applied to the coils 23 and 23′ without displacing them. The coils 23 and 23′ shares the matching box 25 connected to the high frequency generator 24 generating the induced current.

The coils 23 and 23′ may be disposed in the chamber 21. However, it this case, a sputtering phenomenon may occur by the plasma to generate impurities that can be deposited on the substrate 22. Therefore, it is preferable that the coils 23 and 23′ are disposed around the outer circumference of the chamber 21. In addition, it is more preferable that the coils 23 and 23′ are disposed to be movable along the outer circumference of the chamber 21 so that a distance between the coils 23 and 23′ can be adjusted. Since the coils 23 and 23′ are disposed facing each other, sharing the high frequency generator 24, they can simultaneously apply the magnetic field into the chamber 21. As the coils 23 and 23′ are disposed on both sides of the chamber 21, the further uniform magnetic field can be distributed n the chamber.

A process for depositing material on both sides of the substrate using the above-described plasma CVD system will be briefly described hereinafter.

Inertia gas such as Ar is injected into the chamber 21 through the gas injection holes to generate the plasma on both sides of the substrate 22. The inertia gas plasma is diffused on the both sides of the substrate 22 to dissolve the deposition material gas (i.e., Gas 3) injected around the substrate 22, thereby depositing a predetermined layer on the substrate 22.

The uniformity of the deposited layer depends on the plasma density on the substrate 22 as well as the uniform gas flow. The prior one-side CVD system is provided with an exhaust hole formed on a lower portion of a substrate holder so that the flow of the exhaust gas can be centrally realized around the substrate. However, in a both-side CVD system where the substrate is suspended on a central region of the chamber, it is difficult to form a uniform gas flow around the substrate. Therefore, in the present invention, the gas exhaust unit 26 is disposed around the substrate 22 having the outer exhaust hole 26b and the inner exhaust holes 26a, each size of which is increased as it goes away from the outer exhaust hole 26b, thereby inducing the uniform gas flow.

A process for depositing a thin film on a plastic substrate using the above-described plasma CVD embodiment of the present invention will be described hereinafter.

In a TFT manufacturing process for a plastic display, silicon oxide layers such as a protective layer, an interlayer dielectric layer and an intermetallic dielectric layer are deposited by a plasma CVD system. The plastic display has to have high transparency so that it can be employed to a variety of application. Therefore, a transparent oxide layer is coated as a protective layer between an organic substrate and an inorganic deposition layer to enhance the adhesive strength between them. Since the silicon oxide layer is transparent, even when it is coated on the both sides of the substrate, the transparency of the plastic substrate is not deteriorated.

A plastic substrate is first mounted on the substrate holder 22′ of the plasma CVD depicted in FIG. 2A. To make the chamber 21 in a high vacuum state, gas in the chamber 21 is pumped out and the inertia gas such as Ar generating the plasma is injected into the chamber 21. High frequency is applied from the high frequency generator 24 to the coils 23 and 23′ to generate the plasma in the chamber 21. Then, the reacting gases, SiH₄ and N₂O is injected into the chamber 21 through the reacting gas injection holes 26, 26′, 27 and 27′ to coat the both side of the substrate 22 with the silicon oxide layer that is the protective layer. At this point, the plasma generated in the chamber 21 is uniformly distributed on the both sides of the substrate 21, thereby uniformly depositing the silicon oxide layer on the both side of the substrate 21.

The interlayer dielectric layer and the intermetallic dielectric layer are also formed on the both sides of the substrate through the identical process using the plasma CVD system. After the deposition process is completed or during the depositing process is being processed, the gases in the chamber 21 is exhausted out of the chamber 21 through the inner and outer exhaust holes 26a and 26b by the gas exhaust unit 26. As described above, the gas exhaust unit 26 is designed having dual exhaust holes 26a and 26b and each size of the inner exhaust holes 26a is increased as it goes away from the outer exhaust hole 26b.

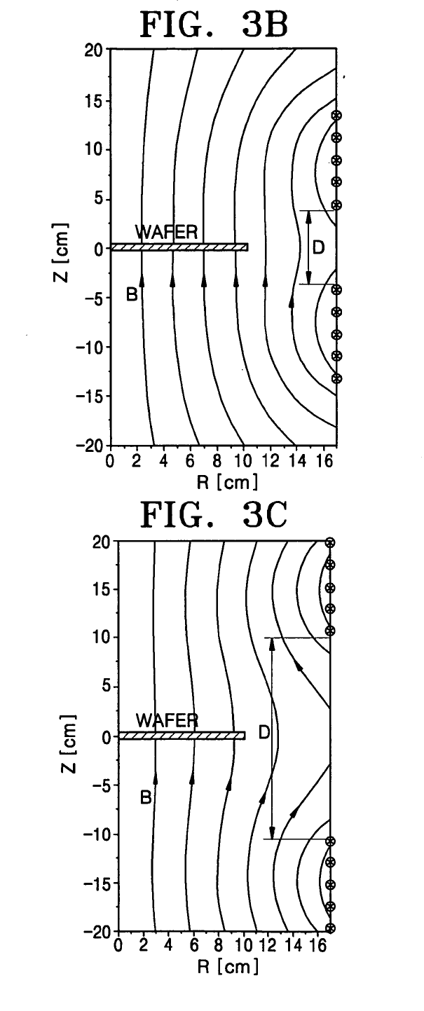

With reference to FIGS. 3A through 3C, a magnetic field generated when a coil is formed on only one side of the chamber will be compared with a magnetic field generated when coils are formed on both sides of the chamber.

FIG. 3A shows a graph illustrating a magnetic field distribution when a single coil is disposed on one side of the chamber.

In the graph, a horizontal axis R indicates a distance in a coil winding direction at a left portion of the chamber and a vertical axis Z indicates a distance in a magnetic filed direction formed in the coil.

As shown in the graph, when the coil is formed only on one side of the chamber, the magnetic file is not uniformly distributed but increased in its width in proportion to a distance from the coil. That is, the movement of the electrons generated in the plasma along the magnetic field becomes irregular and the plasma density is varied according to a location on the substrate.

However, as shown in FIGS. 3B and 3C, when two coils are disposed on both sides of the chamber in the almost symmetrical structure, a uniform magnetic field is distributed around the substrate disposed between the coils by a mutual interference between the magnetic fields formed by the coils. In addition, even when a distance between the coils is varied, the uniform magnetic field is maintained. Accordingly, when opposing two coils are used to coat both sides of a substrate, the more uniform plasma density can be formed on the substrate.

Although the plasma density distribution can be adjusted by adjusting a distance between the coils as shown in FIGS. 3B and 3C, it can be also adjusted by connecting the coils to the respective capacities as shown in FIG. 2A and varying an induced current without varying the distance between the coils.

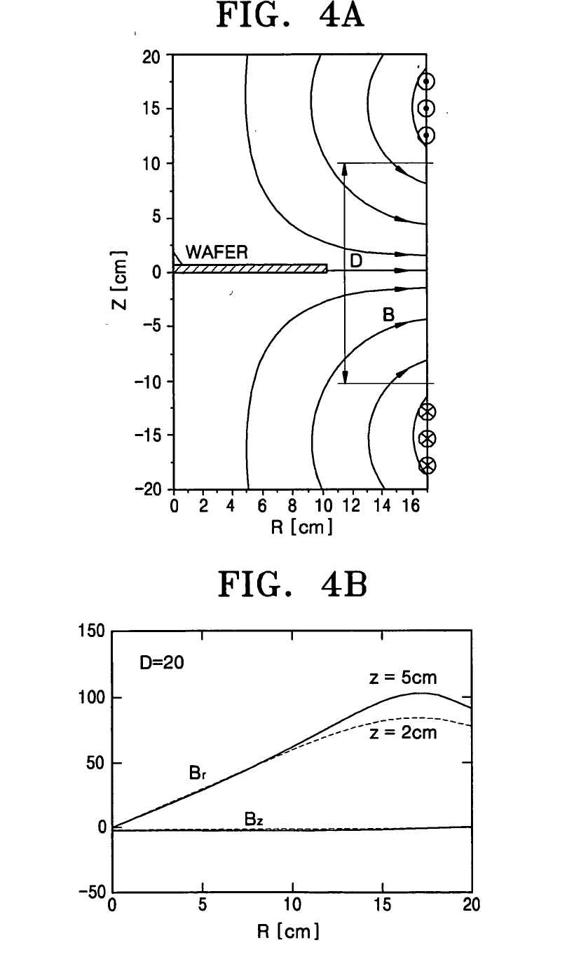

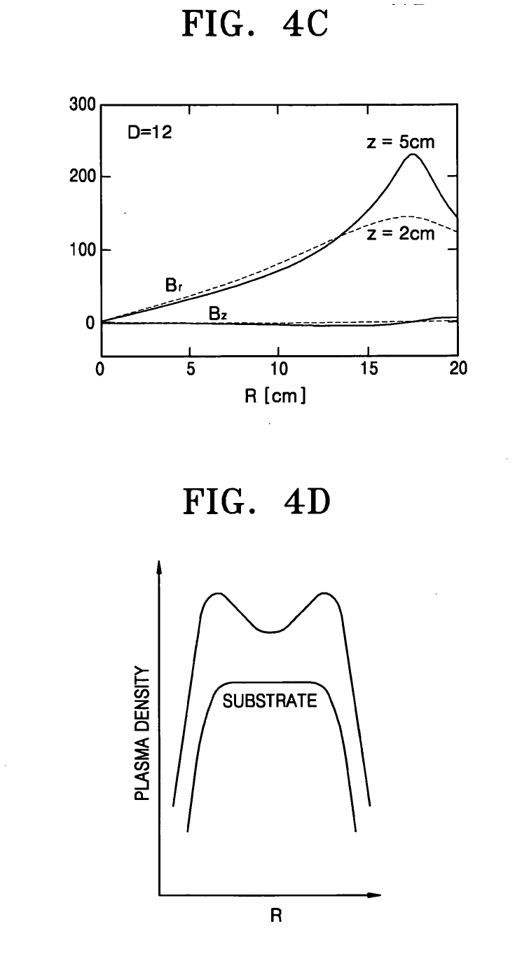

Although FIGS. 3B and 3C show a case where inphase currents flow along the coils, a case where antiphase currents flow along the coils can be applied. At this point, a magnetic field distribution according to a distance between the coils along which the antiphase currents flow is shown in FIGS. 4B and 4C.

FIG. 4A shows a graph illustrating a magnetic field distribution when current flow directions of the coils 23 and 23′ disposed around the chamber 21 shown in FIG. 2A are different from each other, and FIGS. 4B and 4C show graphs illustrating a magnetic field distribution according to a R value of the substrate when a distance (D=12 cm, 20 cm) between the coils is varied.

Referring to FIGS. 4B and 4C, even when antiphase currents flow along the coils, a magnetic field Bz formed in a vertical direction is uniform, not being affected by the distance D between the coils. However, a magnetic field Br in a concentric circular direction is remarkably varied according to a variation of the distance D between the coils. That is, when the distance is reduced from 20 cm to 12 cm, the intensity of the magnetic field is enhanced as the R value of the substrate is increased from 0. That is, a plasma density is reduced as it goes from a wall of the chamber 21 to a center of the chamber 21. This plasma density distribution is of help to provide a uniform radial plasma density around the substrate 22 in a practical application.

FIG. 4D shows a graph illustrating a plasma density distribution on a substrate according to a plasma density distribution on an inner circumference of the chamber 21. Electrons are easily diffused at the wall of the chamber 21 to deteriorate the plasma efficiency. Accordingly, when the plasma density is high at a portion close to the wall of the chamber 21, the plasma density on the substrate 22 mounted on the central portion of the chamber 21 is uniformly distributed as shown in FIG. 4D, thereby uniformly forming a film on the substrate 22.

According to the above-described present invention, the crack, which may be formed by a one-side coating of a flexible substrate such as a plastic substrate, is not formed in the thin film coated on the flexible substrate, a high quality plastic display or a high quality device using the plastic substrate can be obtained.

In addition, since the coils generating the plasma are arranged on an outer circumference of the chamber, the generation of impurities due to the sputtering phenomenon between the plasma and the electrodes can be prevented.

Furthermore, since the location of the coils can be easily displaced along the outer circumference of the chamber, the uniform plasma density can be distributed around the substrate under a desired process condition. When the inphase or antiphase currents flow along the coils, the plasma density can be varied in the concentric circular direction. As a result, the uniform plasma density can be easily obtained on the substrate.

In addition, since the gas exhaust unit for exhausting gas out of the chamber is designed having a main exhaust hole connected to a pump and sub-exhaust holes, each size of which is increased as it goes away from the main exhaust hole.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A plasma chemical vapor deposition system comprising:
a chamber provided with gas injection holes;
a gas exhaust unit mounted on the chamber;
a substrate holder disposed on a central area of the chamber to support a substrate in a state where both sides of the substrate are exposed; and
first and second coils generating induced magnetic fields, the first and second coils being disposed around upper and lower outer circumferences of the chamber, respectively.

2. The plasma chemical vapor deposition system of claim 1, wherein the substrate holder is disposed enclosing an outer circumference of the substrate holder.

3. The plasma chemical vapor deposition system of claim 2, wherein the gas exhaust unit is provided at an inner circumference with an inner gas exhaust hole through which the gas in the chamber is exhausted and at an outer circumference with an outer exhaust hole connected to a pump.

4. The plasma chemical vapor deposition system of claim 2, wherein the inner gas exhaust hole is formed at least two portions of the inner circumference of the gas exhaust unit, each size of the inner exhaust holes being increased as it goes away from the outer exhaust hole.

5. The plasma chemical vapor deposition system of claim 2, wherein the first and second coils may be formed of one of helical type coils or flat antenna type coils.

6. The plasma chemical vapor deposition system of claim 1, wherein the first and second coils are disposed to be movable along the outer circumference of the chamber so that a distance between the first and second coils can be adjustable.

7. The plasma chemical vapor deposition system of claim 1, wherein the first and second coils are symmetrically disposed with reference to the substrate holder.

8. The plasma chemical vapor deposition system of claim 1, wherein first ends of the first and second coils shares a high frequency generator and second ends of the first and second coils are respectively connected to first and second tuning capacitors.

9. The plasma chemical vapor deposition system of claim 1, wherein the gas injection holes are symmetrically formed on opposing ends of the chamber.

10. A plasma chemical vapor deposition method comprising:
disposing a substrate on a substrate holder in a central area of a chamber provided with a gas injection hole and a gas exhaust hole; and
generating uniform induced magnetic fields on both sides of the substrate by applying high frequency to first and second coils between which the substrate is disposed, thereby forming a uniform thin film on the both sides of the substrate.
